(19) United States
(12) Patent Application Publication
(10) Pub. No.: US 2016/0087068 A1
(43) Pub. Date: Mar. 24, 2016

(54) LATERAL BIPOLAR TRANSISTOR WITH BASE EXTENSION REGION

(71) Applicant: International Business Machines Corporation, Armonk, NY (US)

(72) Inventors: Jin Cai, Cortlandt Manor, NY (US); Kevin K. Chan, Staten Island, NY (US); Christopher P. D'Emic, Ossining, NY (US); Tak H. Ning, Yorktown Heights, NY (US); Jeng-Bang Yau, Yorktown Heights, NY (US); Joonah Yoon, Fishkill, NY (US)

(21) Appl. No.: 14/494,626

(22) Filed: Sep. 24, 2014

(51) Int. Cl. H01L 29/66; H01L 29/735

(52) U.S. Cl. CPC H01L 29/6625; H01L 29/735

(57) ABSTRACT

A method of forming a base extension region for a lateral bipolar transistor. The base extension region may include forming an extrinsic base on an intrinsic base layer, the intrinsic base layer is on an insulator layer, a top portion of the intrinsic base layer is exposed on opposite sides of the extrinsic base; forming a base extension region by recessing the exposed top portion of the intrinsic base layer to a recessed surface, the recessed surface is above a top surface of the insulator layer, the base extension region is a region of the intrinsic base layer remaining above the recessed surface; and forming an emitter/collector in the intrinsic base layer, an intrinsic base is a portion of the intrinsic base layer between the emitter/collector, the emitter/collector is a distance from the extrinsic base of no less than a thickness of the base extension region.

### BACKGROUND

The present invention generally relates to semiconductor device manufacturing, and more particularly to the formation of a base extension region in a lateral bipolar transistor.

Parasitic capacitance between the extrinsic base, the emitter, and/or the collector is a performance-limiting factor for a bipolar transistor. The parasitic capacitance reduces the switching speed of the bipolar transistor. Noise generated at the periphery of the base is another performance-limiting factor for a bipolar transistor. Typically, charge carriers can be temporarily captured at an interface between the base and a surrounding dielectric material, and emitted at a subsequent time to introduce electrical noise in the signal. In order to provide signal amplification with high fidelity, such noise must be suppressed to a minimum level. Yet another performance-limiting factor for a bipolar transistor is the maximum current density that the transistor can handle without speed degradation. Further, practical issues of manufacturability, i.e., lower processing cost, shorter processing time, and higher process yield, must be addressed in order to provide a high-performance bipolar transistor that can be commercially manufactured.

### SUMMARY

According to one embodiment of the present invention, a method of forming a base extension region in a lateral bipolar transistor is provided. The method may include forming a semiconductor-on-insulator substrate having a semiconductor layer on a buried insulator layer and the buried insulator layer is on a handle substrate; forming a shallow trench isolation around a portion of the semiconductor layer, the shallow trench isolation is directly on the buried insulator layer, wherein an intrinsic base layer is the portion of the semiconductor layer within the shallow trench isolation; forming an extrinsic base layer on the intrinsic base layer; forming an extrinsic base by patterning a hardmask and etching the hardmask pattern into the extrinsic base layer, the intrinsic base layer is exposed on opposite sides of the extrinsic base; forming a base extension region by recessing the intrinsic base layer on the opposite sides of the extrinsic base to a recessed surface, the recessed surface is a surface below a bottom surface of the extrinsic base and above a top surface of the buried insulator layer, the base extension region is a portion of the intrinsic base layer remaining below the bottom surface of the extrinsic base and above the recessed surface; forming sidewall spacers on sidewalls of the extrinsic base and on sidewalls of the base extension region; and forming an intrinsic base between an emitter and a collector by forming the emitter and the collector in the intrinsic base layer on opposite sides of the extrinsic base, the intrinsic base is a portion of the intrinsic base layer between the emitter and the collector, the emitter is a distance from the extrinsic base of no less than a thickness of the base extension region, the collector is a distance from the extrinsic base of no less than the thickness of the base extension region.

According to another embodiment of the present invention, a method of forming a base extension region in a lateral bipolar transistor is provided. The method may include forming an extrinsic base on an intrinsic base layer, the intrinsic base layer is laterally surrounded by a shallow trench isolation, the intrinsic base layer is on an insulator layer, a top portion of the intrinsic base layer is exposed on opposite sides of the extrinsic base; forming a base extension region by recessing the exposed top portion of the intrinsic base layer to a recessed surface, the recessed surface is a surface below a bottom surface of the extrinsic base and above a top surface of the insulator layer, the base extension region is a region of the intrinsic base layer remaining below the bottom surface of the extrinsic base and above the recessed surface; and forming an emitter/collector in the intrinsic base layer and on opposite sides of the extrinsic base, an intrinsic base is between the emitter/collector, the intrinsic base is a portion of the intrinsic base layer below the base extension region and above the insulator layer, the base extension region is vertically between the extrinsic base from the emitter/collector.

According to another embodiment of the present invention, a structure with a base extension region in a lateral bipolar transistor is provided. The structure may include an emitter and a collector on opposite sides of an intrinsic base; an extrinsic base on a base extension region, the base extension region is on the intrinsic base, the base extension region has a thickness between the extrinsic base and the intrinsic base, the emitter is a distance from the extrinsic base of no less than the thickness of the base extension region, the collector is a distance from the extrinsic base of no less than the thickness of the base extension region; and sidewall spacers on sidewalls of the extrinsic base and on sidewalls of the base extension region.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which:

FIG. 1 is a cross section view of a semiconductor structure, according to an exemplary embodiment.

FIG. 2 is a cross section view of the semiconductor structure and illustrates the formation of a shallow trench isolation (STI) around an intrinsic base layer, according to an exemplary embodiment.

FIG. 3 is a cross section view of the semiconductor structure and illustrates the formation of an extrinsic base layer on the intrinsic base layer, according to an exemplary embodiment.

FIG. 4 is a cross section view of the semiconductor structure and illustrates the formation of an extrinsic base, according to an exemplary embodiment.

FIG. 5 is a cross section view of the semiconductor structure and illustrates the formation of a base extension region, according to an exemplary embodiment.

FIG. 6 is a cross section view of the semiconductor structure and illustrates the formation of sidewall spacers on sidewalls of the extrinsic base and on sidewalls of the base extension region, according to an exemplary embodiment.

FIG. 7 is a cross section view of the semiconductor structure and illustrates the formation of an emitter/collector trench in the intrinsic base layer on each side of the extrinsic base, according to an exemplary embodiment.

FIG. 8 is a cross section view of the semiconductor structure and illustrates the formation of an emitter/collector in the emitter/collector trench, according to an exemplary embodiment.

FIG. 9 is a cross section view of an alternative semiconductor structure and illustrates an ion implantation process, according to an alternative embodiment.

FIG. 10 is a cross section view of the alternative semiconductor structure and illustrates the formation of an emitter/collector in the intrinsic base layer, according to an alternative embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

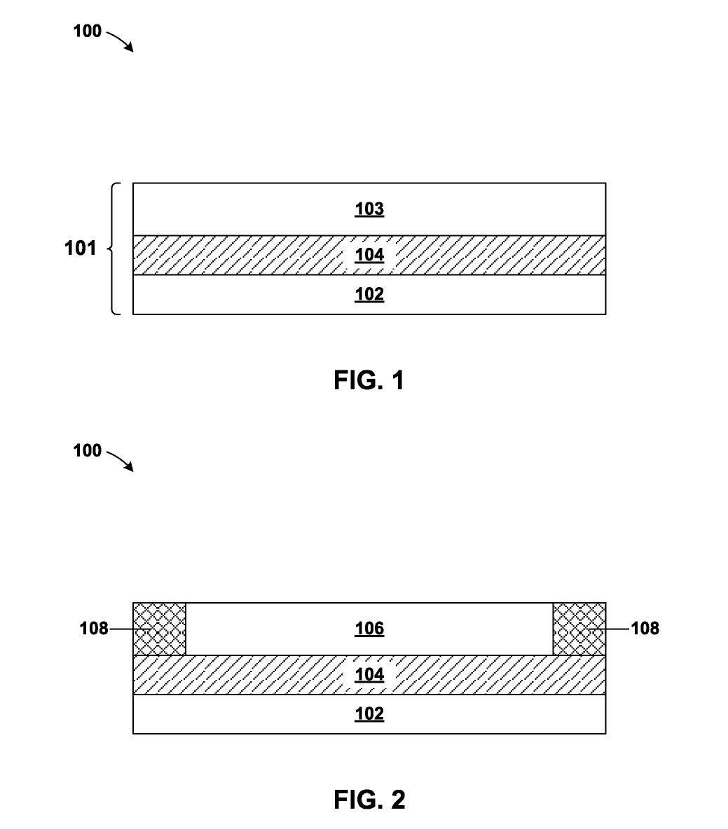

The present invention generally relates to semiconductor device manufacturing, and more particularly to the formation of a base extension region in a lateral bipolar transistor. It should be noted, both homojunction transistors and heterojunction transistors may be employed in the present invention. Ideally, it may be desirable to fabricate a lateral bipolar transistor with a base extension region between an extrinsic base and an emitter/collector to reduce a parasitic capacitance and/or to increase the breakdown voltage of emitter-base and collector-base diodes. One way to fabricate a base extension region in a lateral bipolar transistor is to recess an intrinsic base layer on opposite sides of an extrinsic base, followed by formation of an emitter/collector in the intrinsic base layer on opposite sides of the extrinsic base. One embodiment by which to form the base extension region is described in detail below referring to the accompanying drawings FIGS. 1-8.

FIG. 1 is a demonstrative illustration of a structure 100 during an intermediate step of a method of fabricating a base extension region according to an embodiment. More specifically, the method can start with fabricating a semiconductor layer 103 on a buried insulator layer 104.

In an exemplary embodiment, the intrinsic base layer 106 may be a top layer of a semiconductor-on-insulator (SOI) substrate 101. The SOI substrate 101 may include the semiconductor layer 103 on the buried insulator layer 104 and the buried insulator layer 104 is on a handle substrate 102. The handle substrate 102 may include a semiconductor material, an insulator material, a conductor material, or any combination thereof. In an exemplary embodiment, the handle substrate 102 may include a semiconductor material such as silicon. If the handle substrate 102 includes a semiconductor material, the handle substrate 102 may be; undoped, doped having a p-type doping, or doped having an n-type doping.

The buried insulator layer 104 may be formed on the handle substrate 102. The buried insulator layer 104 may be formed using any deposition technique known in the art, such as, for example, chemical vapor deposition, plasma enhanced chemical vapor deposition, atomic layer deposition, or physical vapor deposition. The buried insulator layer 104 may include any dielectric material known in the art, such as, for example, silicon oxide and/or silicon nitride. In an embodiment, the buried insulator layer 104 may include a silicon oxide. The thickness of the buried insulator layer 104 may range from about 5 nm to about 1000 nm, and typically from about 100 nm to about 200 nm, although lesser and greater thicknesses may also be employed. In an alternative embodiment, the buried insulator layer 104 may include multiple dielectric layers or a stack of dielectric layers including at least a silicon oxide layer and a silicon nitride layer. The buried insulator layer 104 may be used to reduce parasitic capacitance, thereby improving performance.

The semiconductor layer 103 may be formed on the buried insulator layer 104 using any deposition technique known in the art, such as, for example, chemical vapor deposition, plasma enhanced chemical vapor deposition, atomic layer deposition, or physical vapor deposition. Alternatively, the semiconductor layer 103 may be formed by bonding a semiconductor layer directly onto the buried insulator layer 104. In an embodiment, the semiconductor layer 103 may include single crystalline silicon and may be directly on the buried insulator layer 104. The thickness of the semiconductor layer 103 may range from about 10 nm to about 500 nm, and typically from about 30 nm to about 100 nm, although lesser and greater thicknesses may also be employed. The semiconductor layer 103 may be provided as a doped single crystalline semiconductor layer having a doping of a first conductivity type or as a single crystalline intrinsic semiconductor layer (i.e., undoped). The first conductivity type can be p-type or n-type. If the semiconductor layer 103 is a doped single crystalline semiconductor layer, the dopant concentration in the semiconductor layer 103 may be from 1.0×10¹⁷/cm³ to 3.0×10¹⁹/cm³, although lesser and greater dopant concentrations may also be employed. If the semiconductor layer 103 is a single crystalline intrinsic semiconductor layer, the semiconductor layer 103 may be doped with dopants of the first conductivity type immediately after the substrate, or at a subsequent processing step, by performing an ion implantation employing a conventional ion implantation processing step or by performing a plasma doping.

FIG. 2 is a demonstrative illustration of the structure 100 during an intermediate step of a method of fabricating a base extension region according to an embodiment. More specifically, the method may include forming a shallow trench isolation (STI) 108 around an intrinsic base layer 106.

The STI 108 may be formed around a portion of the semiconductor layer 103 and define a boundary of the intrinsic base layer 106. The intrinsic base layer is the portion of the semiconductor layer 103 within the STI 108. The intrinsic base layer 106 may be the same material and thickness as the semiconductor layer 103. The STI 108 may be formed by, for example, patterning a shallow trench surrounding the intrinsic base layer 106 and filling the shallow trench with a dielectric material, such as, for example, silicon oxide and/or silicon nitride. The shallow trench may be formed, for example, by applying and patterning a photoresist, then transferring (i.e., etching) the photoresist pattern through the semiconductor layer 103 to a top surface of the buried insulator layer 104. After removal of the photoresist, a dielectric material may be deposited and subsequently planarized to form the STI 108. The dielectric material may laterally surround and contact the intrinsic base layer 106. The top surface of the STI 108 may be coplanar with a top surface of the intrinsic base layer 106. An optional trench liner may be formed within the shallow trench prior to filling the shallow trench with a dielectric material. Further, an optional densification step may follow the planarization process.

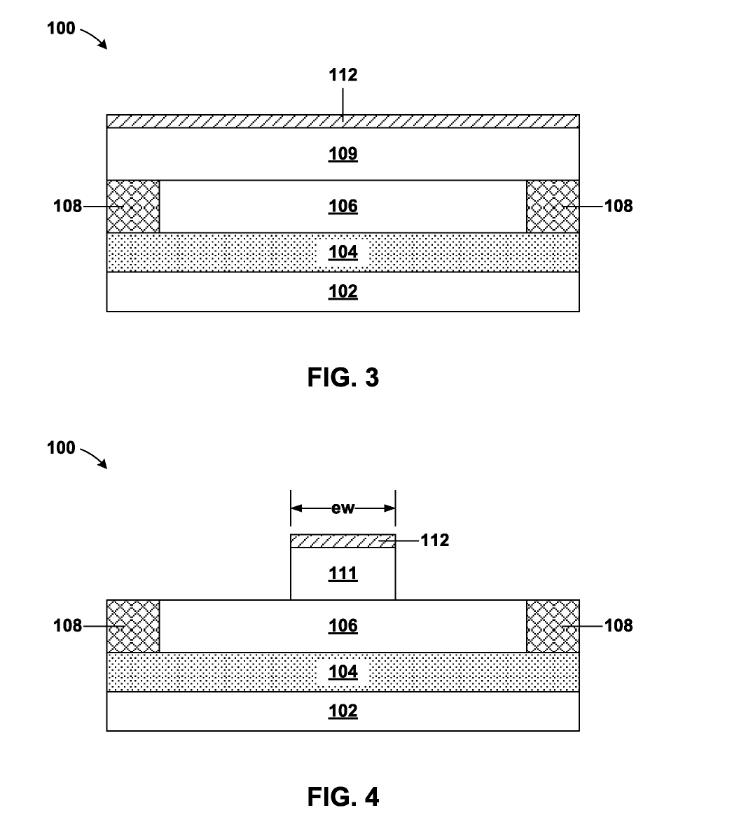

FIGS. 3 and 4 are demonstrative illustrations of the structure 100 during an intermediate step of a method of fabricating a base extension region according to an embodiment. More specifically, the method may include forming an extrinsic base 111 on the intrinsic base layer 106.

The extrinsic base 111 may be formed by depositing and patterning an extrinsic base layer 109. The extrinsic base layer 109 may be formed on the intrinsic base layer 106 using any deposition technique known in the art, such as, for example, chemical vapor deposition, plasma enhanced chemical vapor deposition, atomic layer deposition, or physical vapor deposition. The extrinsic base layer 109 may be any semiconductor material having a doping of the first conductivity type, such as, for example, a doped silicon, a doped silicon-germanium alloy, or any other type of semiconductor material doped with dopants of the first conductivity type. The extrinsic base layer 109 may include a doped polycrystalline semiconductor material or a doped epitaxial semiconductor material that is epitaxially aligned to the intrinsic base layer 106. If the extrinsic base layer 109 includes a doped polycrystalline semiconductor material, the extrinsic base layer 109 can include doped polysilicon, a doped polycrystalline silicon-germanium alloy, or any other type of polycrystalline semiconductor material. If the extrinsic base layer 109 includes a doped epitaxial semiconductor material, the extrinsic base layer 109 can include doped epitaxial (single-crystalline) silicon or a doped epitaxial silicon-containing alloy, such as, a silicon-germanium alloy, a silicon-carbon alloy, or a silicon-germanium-carbon alloy.

In one embodiment, the extrinsic base layer 109 may be deposited with in-situ doping that incorporates dopants of the first conductivity type during deposition. In another embodiment, the extrinsic base layer 109 may be deposited as an intrinsic semiconductor material and subsequently implanted with dopants of the first conductivity type.

The dopant concentration in the extrinsic base layer 109 can range from 1.0×10¹⁸/cm³ to 1.0×10²¹/cm³, although lesser and greater dopant concentrations can also be employed. Typically, the extrinsic base layer 109 has a higher dopant concentration than the intrinsic base layer 106. The thickness of the extrinsic base layer 109 may be from about 20 nm to about 1000 nm, and typically from about 50 nm to about 100 nm, although lesser and greater thicknesses can also be employed.

The extrinsic base 111 may be formed by patterning the extrinsic base layer 109 using a hardmask 112. The hardmask 112 may be formed, on the extrinsic base layer 109, using any technique known in the art, such as, for example, chemical vapor deposition, plasma enhanced chemical vapor deposition, atomic layer deposition, or physical vapor deposition. The hardmask 112 may include any masking material, such as, for example, a nitride. The thickness of the hardmask 112 may be from about 10 nm to about 200 nm, although lesser and greater thicknesses may also be employed. The hardmask 112 may be patterned as is known in the art using a technique, such as, for example, photolithography. The extrinsic base 111 may be formed by transferring the hardmask pattern into the extrinsic base layer 109. The hardmask pattern may be transferred to a top surface of the intrinsic base layer 106. The hardmask pattern may be transferred by etching the extrinsic base layer 109 selective to the intrinsic base layer 106 and/or the STI 108 (i.e., etching the extrinsic base layer 109, using the hardmask 112 as a mask, and using the intrinsic base layer 106 and/or the STI 108 as an etch stop). The extrinsic base 111 may have an extrinsic width (ew) ranging from about 20 nm to about 1000 nm, although lesser and greater widths may also be employed. In an embodiment, the STI 108 may include silicon oxide and the hardmask 112 may include silicon nitride to provide etch selectivity.

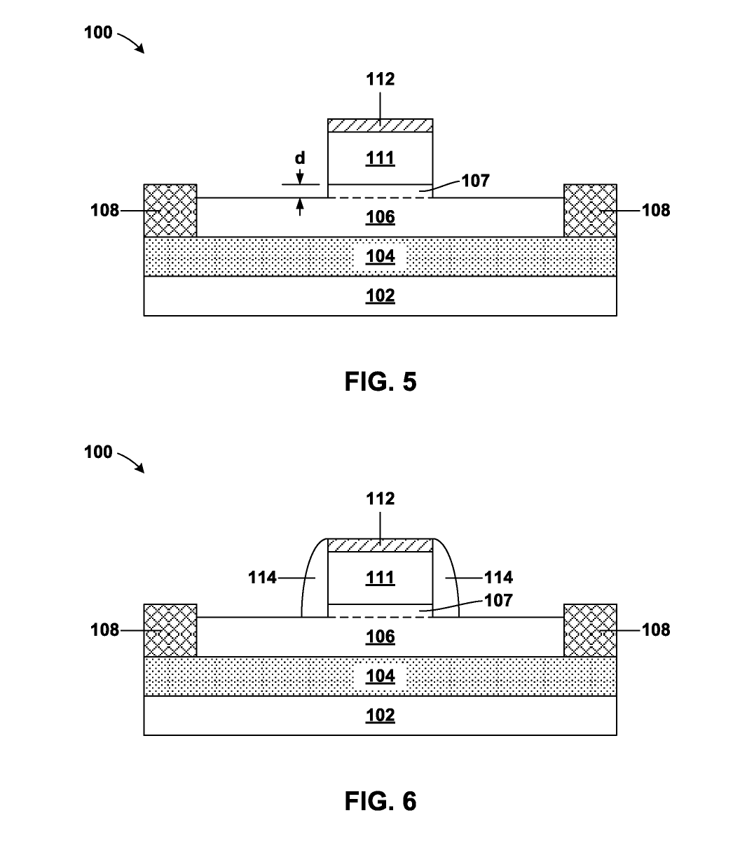

FIG. 5 is a demonstrative illustration of the structure 100 during an intermediate step of a method of fabricating a base extension region according to an embodiment. More specifically, the method may include forming a base extension region 107.

The base extension region 107 may be formed by recessing the intrinsic base layer 106 on opposite sides of the extrinsic base 111. The intrinsic base layer 106 may be recessed using any recessing or trenching technique known in the art, such as, for example, an anisotropic etch. The intrinsic base layer 106 may be recessed from about 2 nm to about 50 nm (“recess depth”), although lesser and greater distances may also be employed. The base extension region 107 may be a portion of the intrinsic base layer 106 below the extrinsic base 111 and above a recessed surface of the intrinsic base layer 106. The base extension region 107 may be the same material as the intrinsic base layer 106 but may have different dimensions. The base extension region 107 may have a thickness (d). The thickness (d) may be the distance from a bottom surface of the extrinsic base 111 to the recessed surface of the intrinsic base layer 106. The thickness (d) may be the same distance as the recess depth in the intrinsic base layer 106.

FIGS. 6, 7, and 8 are demonstrative illustrations of the structure 100 during an intermediate step of a method of fabricating the base extension region 107 according to an embodiment. More specifically, the method may include forming an intrinsic base 116, sidewall spacers 114, and an emitter/collector 138.

In general, the formation of sidewall spacers and emitter/collector regions can be done in any order depending on device design objectives. A device design objective may be, for example, to increase or decrease a base width of an intrinsic base. If the sidewall spacers are formed first, the base width may be larger due to the sidewall spacers decreasing an exposed intrinsic layer surface before forming the emitter/collector. In the alternative, if the emitter/collector is formed first, the base width may be smaller due to the larger exposed intrinsic layer surface at the time of emitter/collector formation. In an exemplary embodiment, the sidewall spacers 114 are formed first.

The sidewall spacers 114 may be formed on the recessed surface using any spacer formation technique known in the art, such as, for example, depositing a dielectric material and anisotropically etching the dielectric material. The sidewall spacers 114 may include a different dielectric material than the hardmask 112, where, for example, the sidewall spacers 114 may include silicon oxide, and the hardmask 112 may include silicon nitride. The sidewall spacers 114 may laterally surround sidewalls of the extrinsic base 111 and the base extension region 107 and may leave an exposed portion of the recessed surface (exposed surface). The exposed surface is the recessed surface less the thickness of the sidewall spacers 114 covering the intrinsic base layer 106.

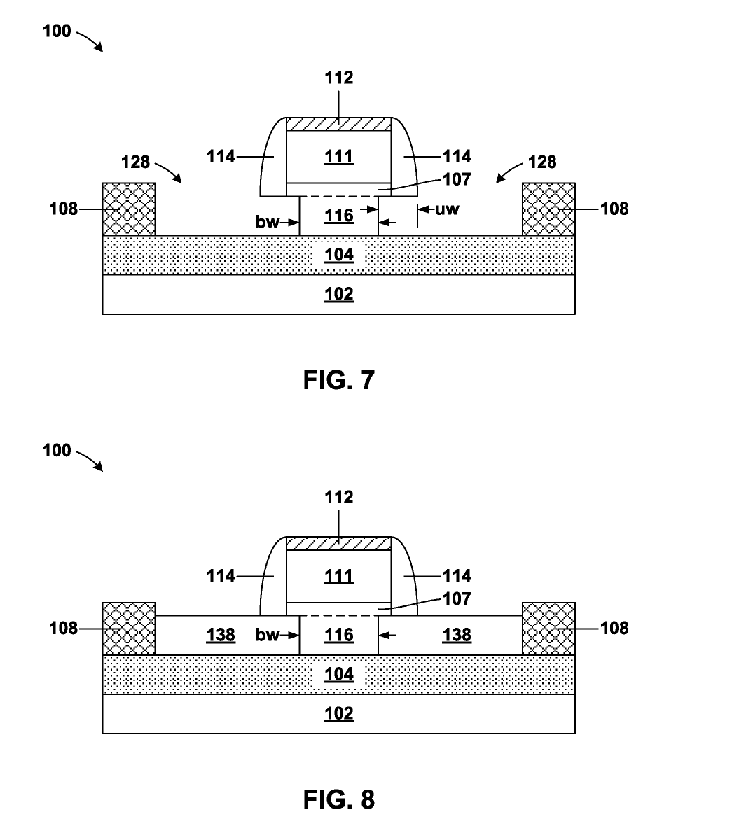

With reference to FIG. 7, in an embodiment, an emitter/collector trench 128 may be formed in the intrinsic base layer 107 on opposite sides of the extrinsic base 111. The emitter/collector trench 128 may be an emitter trench on a first side of the extrinsic base 111 and a collector trench on a second side of the extrinsic base 111, where the first side and the second side are on opposite sides of the extrinsic base. The emitter/collector trench 128 may be formed using any trench formation technique known in the art, such as, for example, an anisotropic etch. The etching technique used may etch the intrinsic base layer 106 at the exposed surface selective to the STI 108, the sidewall spacers 114, the hardmask 112 and the buried insulator layer 104 (i.e., the intrinsic base layer 106 is etched at the exposed surface, the hardmask 112, the sidewall spacers 114 and the STI 108 are used as masks, and the buried insulator layer 104 is used as an etch stop).

An intrinsic base 116 may be the portion of the intrinsic base layer 106 below the base extension region 107 and between the opposite sides of the emitter/collector trench 128 (i.e., between the emitter trench and the collector trench). The intrinsic base 116 may have the same characteristics as the intrinsic base layer 106 but may have different dimensions (e.g., a different width). The intrinsic base 116 may have a base width (bw) between the opposite sides of the emitter/collector trench 128.

There is a possibility of undercutting even when using an anisotropic etching technique, as is used in the exemplary embodiment. The present invention may be best utilized to avoid failure when undercutting is unavoidable, undesired, unknown, or present. The formation of the emitter/collector trench 128 may create an undercut with an undercut width (uw). The undercut width (uw) may be less than, equal to, or greater than, the width of the sidewall spacers 114. The base extension region 107 may become a necessary spacer between the emitter/collector trench 128 and the extrinsic base 111. The need for the base extension region 107 may increase as the undercut width (uw) increases or as the width of the sidewall spacers 114 decreases.

With reference to FIG. 8, an emitter/collector 138 may be formed in the emitter/collector trench 128. The emitter/collector 138 may be an emitter formed in the emitter trench and a collector formed in the collector trench. The emitter/collector 138 may be formed using any emitter/collector formation technique known in the art, such as, for example, selective epitaxy, in which a silicon-containing reactant is flowed into a process chamber to deposit silicon epitaxially on exposed single crystalline surfaces within a trench. The selective epitaxial deposition of silicon may fill the trench to form emitter/collector regions therein. The emitter/collector 138 may have a doping of a second conductivity type, which is the opposite of the first conductivity type. For example, if the first conductivity type is p-type, the second conductivity type is n-type, and vice versa. The emitter/collector 138 may include a doped silicon having a doping of the second conductivity type.

In an embodiment, the emitter/collector 138 may be doped in-situ during the selective epitaxial deposition of silicon. Formation of the emitter/collector 138 with in-situ doping can be effected by flowing a dopant gas including a dopant atom of the second conductivity type concurrently with, or alternately with, a silicon-containing reactant gas. Silicon-containing reactant gases include, but are not limited to, SiH₄, SiH₂Cl₂, SiHCl₃, SiCl₄, and Si₂H₆. If the second conductivity type is n-type, the dopant gas can be, for example, PH₃, AsH₃, SbH₃, or a combination thereof. In another case, the emitter/collector 138 may be deposited as intrinsic silicon portions by selective epitaxy of intrinsic silicon, and are subsequently doped by implanting dopants of the second conductivity type.

An epitaxial layer may be a layer of monocrystalline semiconductor material which grows outward from an exposed surface of an existing monocrystalline semiconductor region or layer. The epitaxial layer may have the same composition as the semiconductor region on which it is grown (e.g., the semiconductor material), impurities (e.g., dopants and their concentrations), or, alternatively, the compositions of the epitaxial layer and the underlying semiconductor region can be different. Sometimes, the epitaxial layer has characteristics that allow the epitaxial layer to impart a stress to the semiconductor region on which it is grown. For example, an epitaxial layer can impart a stress to an adjacent semiconductor region when the epitaxial layer comprises a semiconductor alloy material different from the adjacent semiconductor region, where the epitaxial layer has a different crystal lattice constant than the adjacent semiconductor region lattice constant. Epitaxial films are typically defect-free compared to other deposition methods.

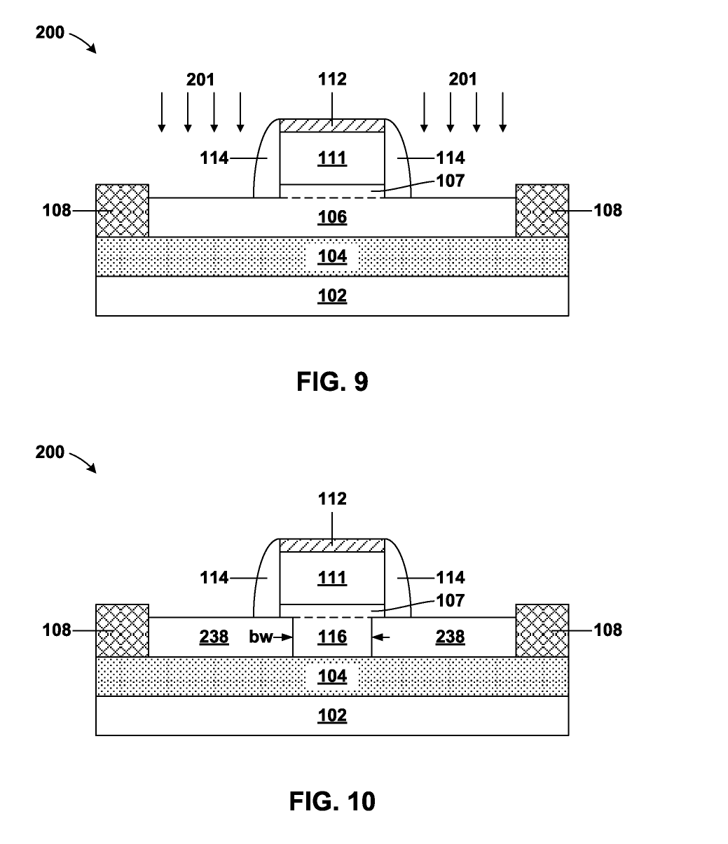

One of many possible alternative embodiments by which to form the base extension region is described in detail below referring to the accompanying drawings FIGS. 9 and 10. FIGS. 9 and 10 are demonstrative illustrations of an alternative structure 200 during an intermediate step of a method of fabricating the base extension region 107, according to an alternative embodiment. More specifically, the method may include forming an emitter/collector 238 using ion implantation 201. It should be noted, FIG. 9 illustrates the alternative structure 200 at the same step of the structure 100 illustrated in FIG. 6. In an alternative embodiment, according to known techniques, the ion implantation 201 may include implanting dopants of the second conductivity type into the intrinsic base layer 106 at the exposed surfaces.

Using any of the several embodiments, a similar structure to the structure 100 illustrated in FIG. 8, or the structure 200 illustrated in FIG. 10, may result. Once the emitter/collector 138 is formed, a shortest distance between the emitter/collector 138 and the extrinsic base 111 may be a same distance as the thickness of the base extension region 107. For example, if a portion of the emitter/collector 138 extends directly underneath the base extension region 107, the distance between the emitter/collector 138 and the extrinsic base 111 is the thickness of the base extension region 107, according to one embodiment. In yet another embodiment, if the emitter/collector 138 only extends partially underneath the sidewall spacers 114 and does not extend underneath the base extension region 107, the distance between the emitter/collector 138 and the extrinsic base 111 will be a distance greater than the thickness of the base extension region 107. Limiting the distance between the emitter/collector 138 and the extrinsic base 111 to at least the thickness of the base extension region 107 is beneficial because of increasing base-collector diode breakdown voltage, and may reduce transistor standby current. Having a more accurate and controllable separation between the emitter/collector 138 and the extrinsic base 111 can also help reduce parasitic capacitance which would help the switching speed of the lateral bipolar transistor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

1. A method of forming a lateral bipolar transistor comprising:
forming a semiconductor-on-insulator substrate having a semiconductor layer on a buried insulator layer and the buried insulator layer is on a handle substrate;
forming a shallow trench isolation around a portion of the semiconductor layer, the shallow trench isolation is directly on the buried insulator layer, wherein an intrinsic base layer is the portion of the semiconductor layer within the shallow trench isolation;
forming an extrinsic base layer on the intrinsic base layer;
forming an extrinsic base by patterning a hardmask and etching the hardmask pattern into the extrinsic base layer, the intrinsic base layer is exposed on opposite sides of the extrinsic base;
forming a base extension region by recessing the intrinsic base layer on the opposite sides of the extrinsic base to a recessed surface, the recessed surface is a surface below a bottom surface of the extrinsic base and above a top surface of the buried insulator layer, the base extension region is a portion of the intrinsic base layer remaining below the bottom surface of the extrinsic base and above the recessed surface;
forming sidewall spacers on sidewalls of the extrinsic base and on sidewalls of the base extension region, wherein the extrinsic base and the base extension region are entirely between the sidewall spacers; and
forming an intrinsic base between an emitter and a collector by forming the emitter and the collector in the intrinsic base layer on opposite sides of the extrinsic base, the intrinsic base is a portion of the intrinsic base layer between the emitter and the collector, the emitter is a distance from the extrinsic base of no less than a thickness of the base extension region, the collector is a distance from the extrinsic base of no less than the thickness of the base extension region, and wherein the emitter and the collector have a top surface that is entirely below the bottom surface of the extrinsic base.

2. The method of claim 1, further comprising:
forming the emitter in an emitter trench and a collector in a collector trench, the emitter trench and the collector trench are in the intrinsic base layer and on the opposite sides of the extrinsic base, the intrinsic base is between the emitter trench and the collector trench.

3. The method of claim 1, wherein the emitter and the collector are formed using ion implantation.

4. The method of claim 1, wherein a top surface of the shallow trench isolation is coplanar with the top surface of the base extension region.

5. The method of claim 1, wherein the intrinsic base layer is a doped single crystalline semiconductor.

6. The method of claim 1, wherein the extrinsic base is a doped polycrystalline semiconductor.

7. The method of claim 2, wherein the emitter and the collector are formed by depositing silicon epitaxially on exposed single crystalline surfaces within the emitter trench and the collector trench.

8. The method of claim 1, wherein the intrinsic base, the base extension region, and the extrinsic base are each of a first conductivity type and the emitter and the collector are of a second conductivity type.

9. The method of claim 1, further comprising:
forming a trench liner around the shallow trench isolation; and
forming an STI liner by densification of the trench liner.

10. A method of forming a lateral bipolar transistor comprising:
forming an extrinsic base on an intrinsic base layer, the intrinsic base layer is laterally surrounded by a shallow trench isolation, the intrinsic base layer is on an insulator layer, a top portion of the intrinsic base layer is exposed on opposite sides of the extrinsic base;
forming a base extension region by recessing the exposed top portion of the intrinsic base layer to a recessed surface, the recessed surface is a surface below a bottom surface of the extrinsic base and above a top surface of the insulator layer, the base extension region is a region of the intrinsic base layer remaining below the bottom surface of the extrinsic base and above the recessed surface; and
forming sidewall spacers on sidewalls of the extrinsic base and on sidewalls of the base extension region, wherein the extrinsic base and the base extension region are entirely between the sidewall spacers; and
forming an emitter/collector in the intrinsic base layer and on opposite sides of the extrinsic base, an intrinsic base is between the emitter/collector, the intrinsic base is a portion of the intrinsic base layer below the base extension region and above the insulator layer, the base extension region is vertically between the extrinsic base from the emitter/collector, and wherein the emitter and the collector have a top surface that is entirely below the bottom surface of the extrinsic base.

11. The method of claim 10, further comprising:
forming an emitter/collector trench in the intrinsic base layer on the opposite sides of the extrinsic base after forming the base extension region; and
forming the emitter/collector in the emitter/collector trench.

12. The method of claim 10, wherein the emitter/collector is formed using ion implantation.

13. The method of claim 10, wherein a top surface of the shallow trench isolation is coplanar with a top surface of the base extension region.

14. The method of claim 10, wherein the intrinsic base layer is a doped single crystalline semiconductor and the extrinsic base is a doped polycrystalline semiconductor.

15. The method of claim 11, wherein the emitter/collector is formed by depositing silicon epitaxially on exposed single crystalline surfaces within the emitter/collector trench.

16. The method of claim 10, wherein the intrinsic base, the base extension region, and the extrinsic base are each of a first conductivity type and the emitter/collector is of a second conductivity type.

17. The method of claim 10, further comprising:
forming a trench liner around the shallow trench isolation; and
forming an STI liner by densification of the trench liner.

18. A lateral bipolar transistor structure comprising:
an emitter and a collector on opposite sides of an intrinsic base;
an extrinsic base on a base extension region, the base extension region is on the intrinsic base, the base extension region has a thickness between the extrinsic base and the intrinsic base, the emitter is a distance from the extrinsic base of no less than the thickness of the base extension region, the collector is a distance from the extrinsic base of no less than the thickness of the base extension region, and wherein the emitter and the collector have a top surface that is entirely below a bottom surface of the extrinsic base; and
sidewall spacers on sidewalls of the extrinsic base and on sidewalls of the base extension region, wherein the extrinsic base and the base extension region are entirely between the sidewall spacers.

19. The structure of claim 18, further comprising:
a hardmask on the extrinsic base.

20. The structure of claim 18, wherein the intrinsic base, the base extension region, and the extrinsic base are each of a first conductivity type and the emitter and the collector are each of a second conductivity type.
